(19) United States
(12) Patent Application Publication
(10) Pub. No.: US 2025/0284203 A1
(43) Pub. Date: Sep. 11, 2025

(54) LITHOGRAPHY SYSTEM AND SEMICONDUCTOR DEVICE MANUFACTURING METHOD USING THE SAME

(71) Applicant: Samsung Electronics Co., Ltd., Suwon-si (KR)

(72) Inventors: Minjae KIM, Suwon-si (KR); Ingyun CHUNG, Suwon-si (KR); Dongjin PARK, Suwon-si (KR)

(73) Assignee: Samsung Electronics Co., Ltd., Suwon-si (KR)

(21) Appl. No.: 19/054,985

(22) Filed: Feb. 17, 2025

(30) Foreign Application Priority Data
Mar. 6, 2024 (KR) 10-2024-0032130

(51) Int. Cl. G03F 7/00

(52) U.S. Cl. CPC G03F 7/70504; G03F 7/70625; G03F 7/70666; G03F 7/706837; G03F 7/706839

(57) ABSTRACT

Disclosed is a program code and a non-transitory computer readable medium including the program code, in which the program code, when executed by a processor, causes an apparatus including the processor to perform operations of selecting a plurality of target patterns from a mask layout, generating an aerial image based on a source system including a plurality of point sources and the mask layout, constructing an objective function based on a plurality of NILS values corresponding to the plurality of target patterns in the aerial image, optimizing the source system such that the objective function has a maximum value, and outputting an optimized source system, and the optimized source system includes a combination of a plurality of effective factors corresponding to the plurality of point sources.

### CROSS-REFERENCE TO RELATED APPLICATIONS

This application claims priority under 35 U.S.C. § 119 to Korean Patent Application No. 10-2024-0032130 filed on Mar. 6, 2024, in the Korean Intellectual Property Office, the disclosures of which are incorporated by reference herein in their entireties.

### BACKGROUND

Embodiments of the present disclosure described herein relate to a source optimizing device, and more particularly, relate to a device for outputting an optimized source system used in a lithography process.

With the advancement of performance required for DRAM (dynamic random-access memory) products through generations, various processes are being developed to refine patterning. Patterning is being refined to tens of nanometers not only in a cell area directly related to DRAM performance but also in core/peri areas.

In particular, a pattern pitch is reduced and reaches a patterning limit in a cell layer, core/peri areas, BEOL (back end of line) metal wiring, and the like. In order to form such an extremely fine pattern, there is a need for improved performance in source optimization in order obtain a source system optimized for fine patterns.

### SUMMARY

Embodiments of the present disclosure provide a source optimization simulation method for outputting a source system with improved patterning quality.

Embodiments of the present disclosure provide a source optimization simulation method for outputting the same optimized source system irrespective of a user's proficiency level.

According to at least one embodiment, a non-transitory computer readable medium comprising a program code, wherein the program code, when executed by a processor, is configured to cause an apparatus including the processor to: select a plurality of target patterns from a mask layout; generate an aerial image based on a source system and the mask layout, the source system including a plurality of point sources; construct an objective function based on a plurality of normalized image log-slope (NILS) values corresponding to the plurality of target patterns in the aerial image; adjust the source system such that the objective function has an increased value; and outputting the adjusted source system as an optimized source system, and the optimized source system includes a combination of a plurality of effective factors corresponding to the plurality of point sources.

According to at least one embodiment, at least one a non-transitory storage medium configured to store a computer program; and at least one processor configured to execute the computer program and to cause the computer to: perform a rendering on a source system including a plurality of point sources, select a plurality of target patterns from a mask layout, generate an aerial image based on the rendered source system and the mask layout, construct an objective function based on a plurality of normalized image log-slope (NILS) values corresponding to the plurality of target patterns in the aerial image, adjusting the source system such that the objective function has an increased value, and output the adjusted source system as an optimized source system, and the optimized source system includes a combination of a plurality of effective factors corresponding to the plurality of point sources.

According to at least one embodiment, a method for manufacturing a semiconductor device using a source optimizing device, a mask manufacturing device, and a lithography device includes performing, using the source optimizing device, operations of selecting a plurality of target patterns from a mask layout, generating an aerial image based on a source system including a plurality of point sources and the mask layout, constructing an objective function based on a plurality of NILS values corresponding to the plurality of target patterns in the aerial image, adjusting the source system such that the objective function has an increased value, and outputting the adjusted source system as an optimized source system; fabricating, by using the mask manufacturing device, a photo mask based on the mask layout; and forming, by using the lithography device, a resist pattern on a wafer by performing a lithography process based on the optimized source system and the photo mask.

### BRIEF DESCRIPTION OF THE FIGURES

The above and other objects and features of the present disclosure will become apparent by describing in detail embodiments thereof with reference to the accompanying drawings.

FIG. 1 is a view illustrating a lithography system according to at least one embodiment of the present disclosure.

FIG. 2 is a block diagram illustrating an implemented embodiment of a source optimizing device according to at least one embodiment of the present disclosure.

FIG. 3A is a view illustrating one example of a lithography device of FIG. 1.

FIG. 3B is a view illustrating another example of the lithography device of FIG. 1.

FIG. 4 is a flowchart illustrating a method of performing a source optimization simulation according to at least one embodiment of the present disclosure.

FIG. 5 is a view illustrating an example of a mask layout.

FIG. 6 is a view for explaining step S120 of FIG. 4.

FIG. 7 is a view for explaining steps S130 and S140 of FIG. 4.

FIG. 8 is a view for explaining an example of a NILS value.

FIG. 9 is a view for explaining step S170 of FIG. 4.

FIG. 10 is a flowchart for explaining a method of manufacturing a semiconductor device using the lithography system of FIG. 1.

### DETAILED DESCRIPTION

Hereinafter, embodiments of the present disclosure will be described clearly and in detail to such an extent that those skilled in the art easily carry out the present disclosure. It will be understood that although numerical terms like “first,” “second,” etc. may be used herein to describe various elements, these elements should not be limited by these terms. These terms are only used to distinguish one element from another. These terms, unless indicated otherwise, do not limit the difference in the materials or structures of the elements.

Components described in the detailed description and function blocks illustrated in drawings may be implemented in the form of processing circuitry, such as software, hardware, or a combination thereof. In at least one embodiment, the software may be a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, and/or a combination thereof. Additionally, in at least some embodiments, the functions and/or operations of the devices may be controlled by the processing circuitry. The processing circuitry may, for example, include and/or execute instructions stored in a non-transitory computer readable media. The term “non-transitory,” as used herein, is a description of the medium itself (e.g., as tangible, and not a signal) as opposed to a limitation on data storage persistency (e.g., RAM vs. ROM). For example, the computer-readable recording medium may be any tangible medium that can store or include the program in or connected to an instruction execution system, equipment, or device.

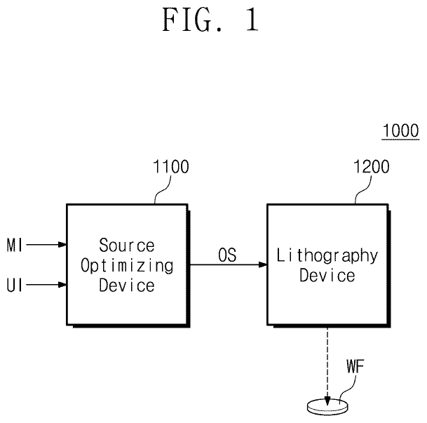

FIG. 1 is a view illustrating a lithography system according to at least one embodiment of the present disclosure. Referring to FIG. 1, the lithography system 1000 may include a source optimizing device 1100 and a lithography device 1200.

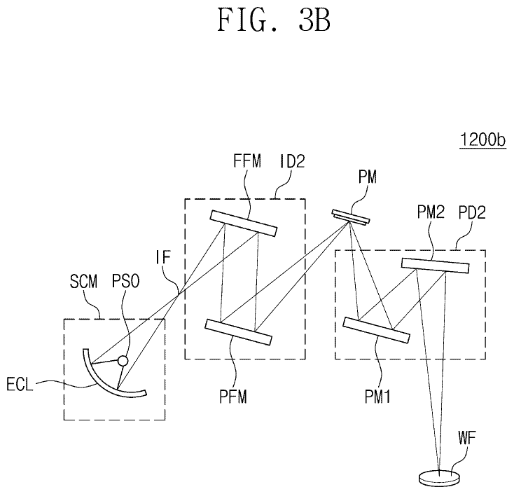

The source optimizing device 1100 may be configured to perform a source optimization simulation based on a mask layout and a user input UI. The source optimizing device 1100 may be configured to output an optimized source system as a result of the source optimization simulation. The optimized source system OS may include a combination of a plurality of effective factors corresponding to a plurality of point sources constituting a source system. Details of performing the source optimization simulation according to the present disclosure in the source optimizing device 1100 will be described below with reference to FIGS. 4 to 9.

The mask layout ML may include a pattern image for manufacturing a photo mask. For example, the pattern image may be an image corresponding to a resist pattern to be manufactured on a wafer through a lithography process. For example, the pattern image of the mask layout ML may include a plurality of unit shapes that are repeatedly arranged. The plurality of unit shapes in the pattern image may have various array forms such as a 1D array, a 2D array, a staggered array, a square array, etc.

The user input UI may include information about process parameters considered when the resist pattern is formed in the lithography process. For example, the user input UI may further include a target critical dimension T_CD that is a target value for the critical dimension of the pattern, a target aspect ratio that is a target value for the aspect ratio of the pattern, constraints on other process parameters, and/or the like.

The lithography device 1200 may be configured to form the resist pattern on the wafer WF using the photo mask. The photo mask is fabricated based on the mask layout ML. For example, the photo mask may be a reticle on which a pattern corresponding to a plurality of patterns on the mask layout ML is formed.

The lithography device 1200 may be configured to perform the lithography process based on light generated from the source system including the plurality of point sources. For example, the lithography device 1200 may be one of a deep ultraviolet (DUV) device, an extreme ultraviolet (EUV) device, a high-NA EUV device, and/or the like.

The source system of the lithography device 1200 may be set based on the optimized source system generated in the source optimizing device 1100. For example, the light intensity distribution of the source system of the lithography device 1200 may be set based on the effective factors of the plurality of point sources of the optimized source system.

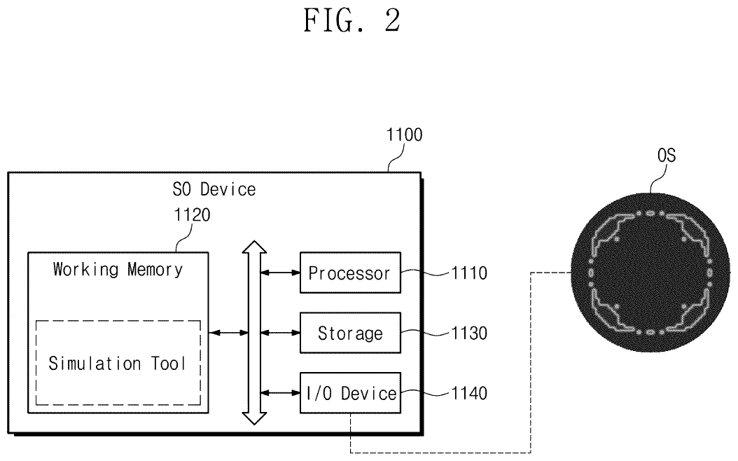

FIG. 2 is a block diagram illustrating an implemented embodiment of the source optimizing device 1100 according to at least one embodiment of the present disclosure.

Referring to FIG. 2, the source optimizing device 1100 may include at least one processor 1110, working memory 1120, storage 1130, and an input/output device 1140. Here, the source optimizing device 1100 may be provided as a dedicated device for performing the source optimization simulation according to at least one embodiment of the present disclosure. For example, the source optimizing device 1100 may be configured to execute a simulation tool that performs the source optimization simulation according to at least one embodiment of the present disclosure. However, without being limited thereto, the source optimizing device 1100 may be configured to additionally execute various simulation programs.

The processor 1110 may execute software (e.g., an application program, an operating system, and a device driver) that is to be performed in the source optimizing device 1100. The processor 1110 may execute an operating system OS loaded into the working memory 1120. The processor 1110 may execute various application programs to be executed based on the operating system OS. The processor 1110 may execute the source optimization simulation loaded into the working memory 1120 from the storage 1130.

The operating system OS or application programs may be loaded into the working memory 1120. When the source optimizing device 1100 is booted and/or when the source optimization simulation is initiated, an OS image stored in the storage 1130 may be loaded into the working memory 1120, e.g., according to a booting sequence. All input/output operations of the source optimizing device 1100 may be supported by the operating system OS. Likewise, application programs may be loaded into the working memory 1120 through selection by a user or for provision of basic services.

In particular, the source optimization simulation tool for source optimization of the present disclosure may also be loaded into the working memory 1120 from the storage 1130. The source optimization simulation tool, when executed by the processor, may cause the processor to output the optimized source system based on the mask layout ML and the user input UI.

The working memory 1120 may include volatile memory such as static random access memory (SRAM) or a dynamic random access memory (DRAM). However, the working memory 1120 is not limited thereto.

The storage 1130 is provided as a storage medium of the source optimizing device 1100. The storage 1130 may store application programs, an operating system image, and various types of data. In particular, the source optimization simulation tool according to at least one embodiment of the present disclosure may be included in the application programs stored in the storage 1130.

The source optimization simulation tool of the present disclosure may be a computer program product including a computer-readable program code or may be a computer program product including a non-transitory computer-usable medium including a computer-readable program code. Additionally or alternatively, the source optimization simulation tool of the present disclosure may be a product downloadable from the Internet.

For example, the storage 1130 may be implemented with a solid state drive (SSD), an embedded multi-media card (eMMC), a hard disk drive (HDD), and/or the like. The storage 1130 may include NAND flash memory. However, without being limited thereto, the storage 1130 may include NOR flash memory or non-volatile memory, such as phase-change RAM (PRAM), magneto-resistive RAM (MRAM), resistive RAM (ReRAM), ferroelectric RAM (FRAM), and/or the like.

The input/output device 1140 may include various devices, such as a communication port, serial bus port, a keyboard, a mouse, a monitor, etc., configured to receive information from user (e.g., a designer) and/or providing information to the designer. For example, the values of various pieces of target information of the user input UI of the source optimization simulation tool may be set through the input/output device 1140, and a processing process and an outcome of the processing may be displayed through the input/output device 1140.

In particular, the optimized source system generated according to embodiments of the present disclosure may be output through the input/output device 1140. A source system may be set in the lithography device based on the optimized source system.

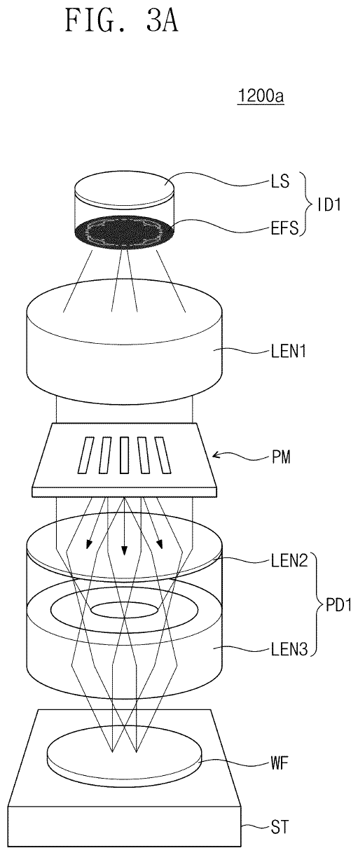

FIG. 3A is a view illustrating an example of the lithography device (1200) of FIG. 1. Referring to FIG. 3A, the lithography device 1200a includes a first illumination device ID1 and a first projection device PD1. In at least one embodiment, the lithography device 1200a may be a DUV device.

The illumination device ID1 may include and/or be connected to a light source LS. The light source LS is configured to generate light. For example, the light may be an electromagnetic spectrum in a DUV band (e.g., a wavelength band of 100 nanometers to 300 nanometers) that is emitted by plasma. For example, the light may be generated by, e.g., discharge plasma of argon fluoride (ArF) gas, krypton fluoride (KrF) gas, and/or the like.

The first illumination device ID1 may be configured to provide the light emitted from the light source LS to a photo mask PM. The photo mask PM may be a transmissive photo mask. The first illumination device ID1 may include an effective projection lens EFS and a first lens LEN1.

The effective projection lens EFS may be configured to control the shape of the light based on the optimized source system. In at least one embodiment, the light transmitting through the effective projection lens EFS may have an intensity distribution that is the same as the intensity distribution of the plurality of point sources in the optimized source system. The first lens LEN1 may be configured to allow the light transmitting through the effective projection lens EFS to travel to the photo mask PM. For example, the first lens LEN1 may be a convex lens. Patterned light may be generated while the light transmitting through the first lens LEN1 transmits through the photo mask PM.

The first projection device PD1 may include a second lens LEN2 and a third lens LEN3. The patterned light may be sequentially reflected by the second lens LEN2 and the third lens LEN3 and may be applied to the wafer WF on a wafer support ST.

However, the present disclosure is not limited to that illustrated in the drawing, and more lenses may be included in the first illumination device ID1 and the first projection device PD.

FIG. 3B is a view illustrating another example of the lithography device (1200) of FIG. 1. In at least one embodiment, the lithography device 1200b may be an EUV device. Referring to FIG. 3B, the lithography device 1200b includes a source collector module SCM, a second illumination device ID2, and a second projection device PD2. In at least one embodiment, the lithography device 1200b may be an EUV device.

The source collector module SCM may include a plasma source PSO and a radiation collector ECL.

The plasma source PSO is configured to generate light. For example, the light may be an electromagnetic spectrum in an EUV band (e.g., a wavelength band of 10 nanometers to 20 nanometers) that is emitted by, e.g., high-temperature discharge plasma. For example, the light may be generated by discharge plasma of gas or vapor, such as Xe gas, Li vapor, Sn vapor, and/or the like.

The radiation collector ECL may be configured to focus the light to an intermediate focus IF. The intermediate focus IF may be a point to which the light is focused and may be referred to as a virtual EUV point source. That is, it may be considered that the light is emitted from the intermediate focus IF. The radiation collector ECL may be, for example, a parabolic reflector configured to reflect the light towards an intermediate focus IF.

The second illumination device ID2 may be configured to provide the light emitted from the intermediate focus IF to a photo mask PM. The photo mask PM may be a reflective photo mask.

The second illumination device ID2 may include a field facet mirror FFM and a pupil facet mirror PFM. The field facet mirror FFM may reflect the light toward the pupil facet mirror PFM, and the pupil facet mirror PFM may be configured to focus the light to the photo mask PM.

The field facet mirror FFM may include a plurality of first reflective elements, and the pupil facet mirror PFM may include a plurality of second reflective elements. Each of the plurality of first reflective elements of the field facet mirror FFM may be configured to reflect the light to one of the plurality of second reflective elements of the pupil facet mirror PFM.

In this specification, a plurality of point sources may refer to the plurality of second reflective elements at points where the light is reflected from the pupil facet mirror PFM.

In at least one embodiment, the second reflective elements corresponding to the plurality of point sources of the optimized illumination system output from the source optimizing device 1100 may be turned on. In this specification, when the point sources are turned on, this may mean that the first reflective elements of the field facet mirror FFM are disposed such that the light is reflected from the second reflective elements at the positions of the point sources on the pupil facet mirror PFM.

Patterned light may be generated when the light is reflected by the photo mask PM.

The second projection device PD2 may include a first projection mirror PM1 and a second projection mirror PM2. The patterned light may be sequentially reflected by the first projection mirror PM1 and the second projection mirror PM2 and may be applied to the wafer WF.

More mirrors or lenses may be included in the second illumination device ID2 and the second projection device PD2.

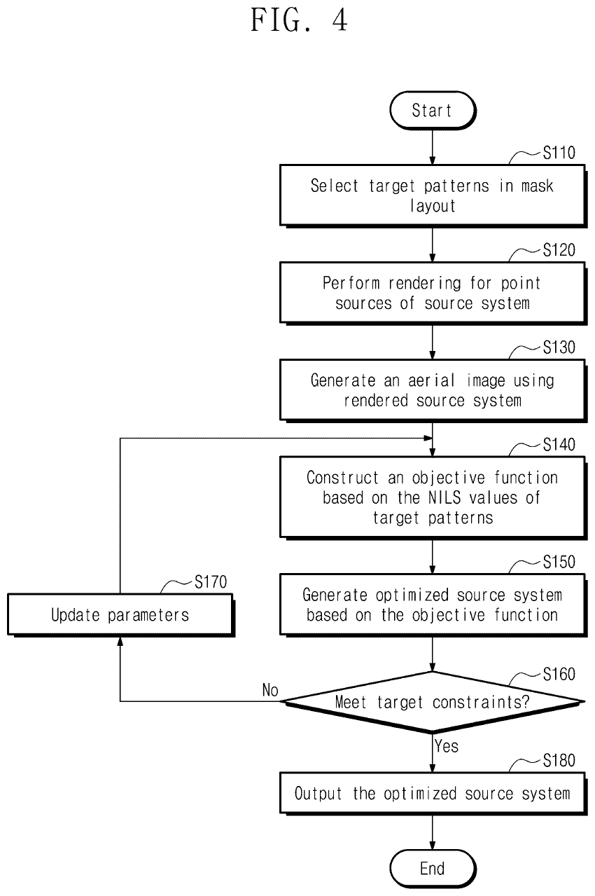

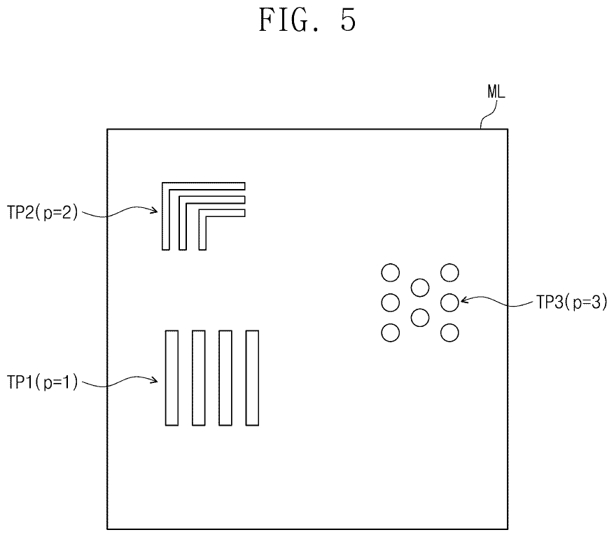

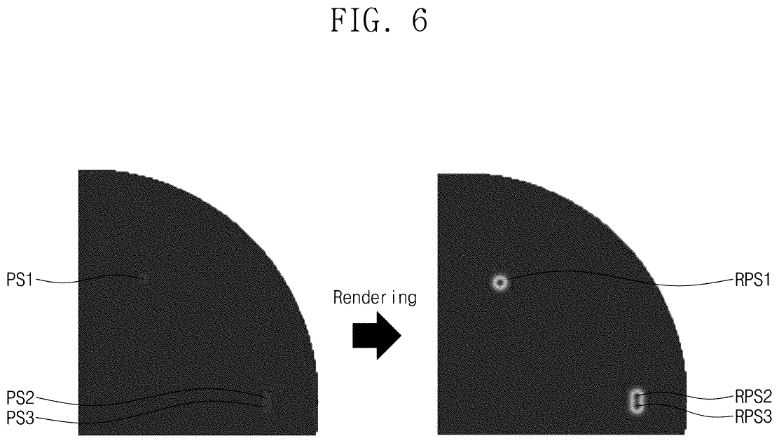

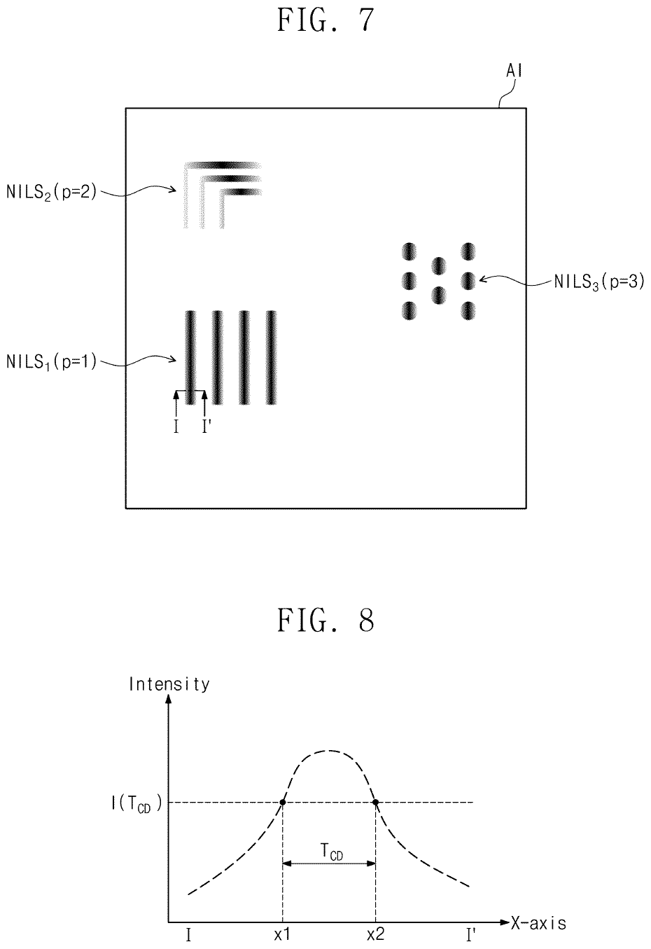

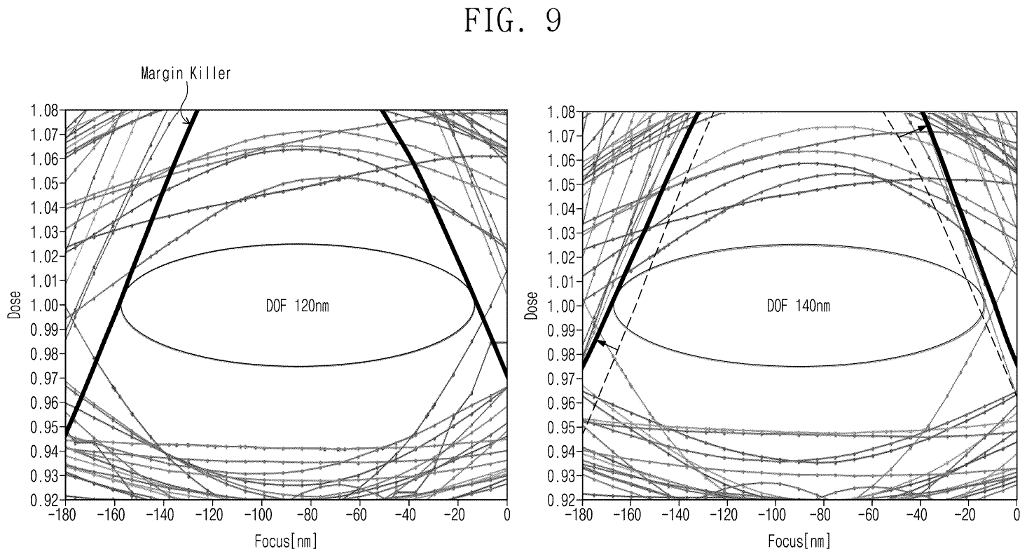

FIG. 4 is a flowchart illustrating a method of performing a source optimization simulation according to at least one embodiment of the present disclosure. FIG. 5 is a view illustrating an example of the mask layout ML. FIG. 6 is a view for explaining step S120 of FIG. 4. FIG. 7 is a view for explaining steps S130 and S140 of FIG. 4. FIG. 8 is a view for explaining an example of a NILS value. FIG. 9 is a view for explaining step S170 of FIG. 4.

Referring to FIGS. 4 and 5, in step S110, the source optimizing device 1100 may select a plurality of target patterns from the mask layout ML. The mask layout ML may be used to manufacture a pattern mask and may include a plurality of patterns. For example, the source optimizing device 1100 may select a first target pattern TP1, a second target pattern TP2, and a third target pattern TP3 from the plurality of patterns.

For example, the first target pattern TP1 may be a straight pattern, the second target pattern TP2 may be an angled pattern, and the third target pattern TP3 may be a circular pattern. The shapes and sizes of the first to third target patterns TP1 to TP3 may vary depending on a cell area, a core area, a peri area, metal wiring, an active area, etc., that are to be formed on a wafer. That is, in the present disclosure, a source system optimized to be suitable for target patterns having various shapes and sizes may be output.

For convenience of description of the present disclosure, it has been described that three target patterns are selected. However, the present disclosure is not limited thereto, and the number of selected target patterns may be increased or decreased according to the needs of those skilled in the art.

Referring to FIGS. 4 and 6, in step S120, the source optimizing device 1100 may be configured to perform rendering on a plurality of point sources in a source system. The source optimizing device 1100 may generate a rendered source system by performing the rendering. The rendered source system may include a plurality of rendered point sources.

In at least one embodiment, the plurality of point sources in the source system may be expressed as a plurality of pixels. Each of the pixels may refer to a point source corresponding thereto. That is, the plurality of point sources in the source system may be distinguished on a pixel-by-pixel basis. The rendering may be intended to reflect optical characteristics such as refraction, diffraction, scattering, and reflection of light generated from each of the plurality of point sources.

In at least one embodiment, the source optimizing device 1100 may make the point sources in a pixel unit subject to rendering by performing a convolution operation using a Gaussian kernel on each of the plurality of pixels of the source system. The Gaussian kernel K_{Gauss}, which is created by approximating a Gaussian distribution function, may be expressed as Equation 1 below.

$${K}_{G auss} ( {σ}_{x} , {σ}_{y} ) = exp [ α ( {σ}_{x}^{2} + {σ}_{y}^{2} ) ] \qquad [ Equation 1 ]$$

In Equation 1, σₓ means the distance from the center (origin) of the Gaussian kernel in the x-axis direction (e.g., the absolute value of the x-coordinate), σ_{y} means the distance from the center of the Gaussian kernel in the y-axis direction (e.g., the absolute value of the y-coordinate), and a is a constant.

The source optimizing device 1100 may generate a first rendered point source RPS1 by performing the convolution operation using the Gaussian kernel on a pixel of a first point source PS1 and neighboring pixels. For example, when the convolution operation is performed, the value of the pixel of the first point source PS1 may be set to “1”, and the values of the neighboring pixels may be set to “0”. For example, the first rendered point source RPS1 may be expressed as a Gaussian distribution of the pixel of the first point source PS1 and the neighboring pixels.

Likewise, the source optimizing device 1100 may generate a second rendered point source RPS2 by performing the convolution operation on a pixel of a second point source PS2 and may generate a third rendered point source RPS3 by performing the convolution operation on a pixel of a third point source PS3. The second rendered point source RPS2 may be expressed as an intensity distribution of the pixel of the second point source PS2 and the neighboring pixels, and the third rendered point source RPS3 may be expressed as an intensity distribution of the pixel of the third point source PS3 and the neighboring pixels.

In at least one embodiment, the plurality of point sources in the source system may be independently controlled. For example, among the plurality of point sources, the first point source PS1 may be turned on, and the remaining point sources may be turned off. In another example, among the plurality of point sources, the first to third point sources PS1 to PS3 may all be turned on. When the second point source PS2 and the third point source PS3 adjacent to each other are simultaneously turned on, the intensity distribution of the pixels of the second rendered point source RPS2 may overlap the intensity distribution of the pixels of the third rendered point source RPS3.

However, the rendering technique is not limited thereto, and various rendering techniques may be applied to reflect the optical characteristics of the point sources according to the needs of those skilled in the art.

In the present disclosure, the source optimizing device 1100 may perform the rendering on the source system before performing optimization of a loss function to be described below. Accordingly, it is possible to prevent degradation in patterning quality that occurs when rendering is performed after an optimized source system is generated.

In step S130, the source optimizing device 1100 may generate an aerial image using the rendered source system. The aerial image may refer to an intensity distribution of light deformed by an optical element when an exposure process is performed on a wafer using a photo mask fabricated based on the mask layout ML. For example, the aerial image may include information about an intensity distribution of light reaching a photoresist film on the wafer.

Referring to FIGS. 4 and 7, in at least one embodiment, the source optimizing device 1100 may be configured to calculate an image log-slope value in each of the plurality of target patterns based on the aerial image. For example, the image log-slope value may be a normalized image log-slope (NILS) value.

In at least one embodiment, the source optimizing device 1100 may calculate the image log-slope value based on the target critical dimension in each of the plurality of target patterns. For example, the source optimizing device 1100 may calculate a first NILS value based on a first target critical dimension of the first target pattern TP1, may calculate a second NILS value based on a second target critical dimension of the second target pattern TP2, and may calculate a third NILS value based on a third target critical dimension of the third target pattern TP3.

In at least one embodiment, the NILS value in each of the target patterns may be calculated based on Equation 2 below.

$$NILS = \frac{1}{I} \cdot \frac{dI}{dx} \qquad [ Equation 2 ]$$

In Equation 2, “x” means the coordinate on the X-axis of the aerial image. “I” is a value in the aerial image and means the intensity of light reaching the wafer. “I” may be expressed as Equation 3 below.

$$I = {\sum }_{i} {g}_{i} {I}_{i} \qquad [ Equation 3 ]$$

In Equation 3, Iᵢ means the intrinsic intensity of the i-th point source in the source system. When the source system is constituted by 100 point sources, “i” may be a natural number from 1 to 100.

In Equation 3, gᵢ is a weighting value (hereinafter, referred to as the effective factor) for controlling the intensity of the i-th point source and may be controlled in the range [0, 1]. For example, when the first point source PS1 (i=1) is set to an intensity of 100% in the source system, g₁ is equal to 1. When the second point source PS2 (i=2) is set to an intensity of 50% in the source system, g₂ is equal to 0.5, and when the third point source PS3 (i=3) is set to an intensity of 0% in the source system, g₃ is equal to 0.

Referring to Equation 2 and Equation 3, “I” may be expressed as a function with effective factors as variables. Likewise, the NILS value may be understood as a function for the effective factor gᵢ.

In step S140, the source optimizing device 1100 may construct an objective function based on the plurality of NILS values for the plurality of target patterns in the aerial image. The objective function may be linearly constructed for the plurality of NILS values. In other words, the objective function may be expressed as a linear equation for the plurality of NILS values. In the objective function, a target weighting value may be allocated to each NILS value (that is, the objective function may be expressed as the product of the NILS value and the target weighting value).

In at least one embodiment, the objective function may be expressed as Equation 4 below.

$$f = {\sum }_{P} {w}_{P} {NILS}_{P} \qquad [ Equation 4 ]$$

In Equation 4, NILSₚ means the NILS value of the p-th target pattern (p being a natural number), and Wp means the target weighting value corresponding to the p-th target pattern. For example, NILS₁ is the first NILS value of the first target pattern TP1, NILS₂ is the second NILS value of the second target pattern TP2, and NILS₃ is the third NILS value of the third target pattern TP3. The target weighting value may be set to an initial value depending on the user input UI. However, as will be described below, the target weighting value may be updated in step S170.

As described above through Equation 2 and Equation 3, NILSₚ may be expressed as a function for the effective factor gᵢ, and the objective function may also be interpreted as a function for the effective factor gᵢ.

In step S150, the source optimizing device 1100 may output an improved or optimized source system by improving and/or optimizing the effective factors corresponding to the plurality of point sources based on the objective function. In at least one embodiment, the source optimizing device 1100 may output the optimized source system by calculating a combination of effective factors by which the objective function of Equation 4 has an increased (and/or maximum) value.

The source optimizing device 1100 may generate the optimized source system in which the objective function has the maximum value, based on a target value for process parameters. The target value for the process parameters may be provided as the user input UI.

In at least one embodiment, a target value for a specific process parameter may be set as an equality condition. Through the Lagrange multiplier method based on Equation 5 below, the source optimizing device 1100 may calculate the combination of the effective factors by which the objective function has the maximum value.

$$L ( X , λ ) = f ( X ) + λ * g ( X ) \qquad [ Equation 5 ]$$

In Equation 5, f(X) is the objective function of Equation 4, g(X) is the equality condition, λ is a Lagrange multiplier, and X is a variable vector and may include a plurality of variables of the objective function. For example, the variable vector X in the objective function of Equation 4 may be a plurality of effective factors.

The source optimizing device 1100 may calculate a plurality of variables and a Lagrange multiplier that satisfy the Lagrange function L(X) for the plurality of variables, the gradient of λ, the gradient of the equality condition, and the condition of Equation 6 below that allows the equality condition to be 0 (zero).

$$∇ L ( X , λ ) = ∇ f ( X ) + λ * ∇ g ( X ) = 0 , g ( X ) = 0 \qquad [ Equation 6 ]$$

The source optimizing device 1100 may be configured to generate the optimized source system by extracting a combination of effective factors by which a loss function has a maximum value under an equality condition for a specific process parameter, based on Equation 5 and Equation 6.

Referring to FIGS. 4 and 8 together, a graph of the intensity distribution of light in the X-axis direction along line I-I′ in the first target pattern TP1 of the aerial image is provided in FIG. 8.

In at least one embodiment, as in Equation 7 below, a target value for a target critical dimension may be set based on the user input UI.

$$I ( {T}_{CD} ) = {I}_{th} \qquad [ Equation 7 ]$$

In Equation 7, I(T_{CD}) means the I value at two x-coordinates that have the same I value and differ from each other by the target critical dimension. For example, when the distance between a first x-coordinate x1 and a second x-coordinate x2 is the target critical dimension, I(T_{CD}) may be obtained by substituting x=x1 into Equation 2. Iₜₕ is a constant and means a target value corresponding to the target critical dimension. In this case, the equality condition may be defined as Equation 8 below.

$$g ( X ) = I ( {T}_{CD} ) - {I}_{th} = 0 \qquad [ Equation 8 ]$$

Accordingly, by combining Equation 4 and Equation 8 with Equation 5, the Lagrange function may be expressed as Equation 9 below.

$$L ( {g}_{i} , λ ) = f ( {g}_{i} ) + λ * ( I - {I}_{th} ) \qquad [ Equation 9 ]$$

In Equation 9, the Lagrange function is a function with a plurality of effective factors and a Lagrange multiplier as variables. The Lagrange function may have a dimension of the same number of effective factors as the plurality of point sources of the source system.

In at least one embodiment, a target value for a specific process parameter may be added as an inequality condition. The source optimizing device 1100 may optimize the objective function through the Lagrange multiplier method based on Equation 10 below under the Karush-Kuhn-Tucker (KKT) condition.

$$L ( X , λ , μ ) = f ( X ) + λ g ( X ) + μ h ( X ) \qquad [ Equation 10 ]$$

In Equation 10, g(X) is the equality condition, h(X) is the inequality condition, A is the first Lagrange multiplier for the equality condition, u is the second Lagrange multiplier for the inequality condition, and X is a variable vector.

The source optimizing device 1100 may calculate a combination of effective factors that satisfy the condition of Equation 11 below to meet the KKT condition.

$$∇ L ( X , λ , μ ) = 0 , g ( X ) = 0 , h ( X ) \leq 0 , μ \geq 0 , μ * h ( X ) = 0 , i = 1 , 2 , … , m \qquad [ Equation 11 ]$$

In at least one embodiment, based on user input UI, a target value for a pupil fill ratio (PFR) may be set by the inequality of Equation 12 below. The pupil fill ratio may be an indicator related to the ratio at which light generated from a light source transmits through a lens or the ratio at which light generated from a light source is reflected from a mirror.

$$PFR = {\sum }_{i} {g}_{i} \leq k \qquad [ Equation 12 ]$$

In Equation 12, gᵢ is the same as the effective factor in Equation 3, and k is a constant and means the target value of the PFR. In this case, the equality condition may be defined as Equation 13 below.

$$h ( {g}_{i} ) = {\sum }_{i} {g}_{i} - k \leq 0 \qquad [ Equation 13 ]$$

Accordingly, by combining Equation 4, Equation 8, and Equation 13 with Equation 10, the Lagrange function may be expressed as Equation 14 below.

$$L ( {g}_{i} , λ , μ ) = f ( {g}_{i} ) + λ * ( I - {I}_{th} ) + μ ( {\sum }_{i} {g}_{i} - k ) \qquad [ Equation 14 ]$$

The source optimizing device 1100 may convert the Lagrange function of Equation 10 into a dual function based on the Lagrange duality principle. The dual function may be expressed as Equation 15 below.

$$g ( λ , μ ) = {}_{X}^{min} L ( X , λ , μ ) \qquad [ Equation 15 ]$$

The source optimizing device 1100 may calculate the first Lagrange multiplier and the second Lagrange multiplier that minimize the dual function.

As described above, in the present disclosure, a multi-dimensional optimization problem including a plurality of variables (a plurality of effective factors) may be converted into an optimization problem for two variables (e.g., the first Lagrange multiplier and the second Lagrange multiplier).

In at least one embodiment, the source optimizing device 1100 may perform global optimization on the dual function using the accelerated gradient descent (AGD) method.

In step S160, the source optimizing device 1100 may determine whether a constraint on a process parameter is met, based on the optimized source system. The constraint on the process parameter may be set based on the user input UI.

The source optimizing device 1100 may generate an aerial image based on the optimized source system in step S150, may extract a process parameter based on the generated aerial image, and may determine whether the extracted process parameter meets the constraint.

In response to the determination result in step S160 that the extracted process parameter does not meet the constraint, the source optimizing device 1100 may update parameters in step S170. For example, the source optimizing device 1100 may update the plurality of target weight values for the plurality of target patterns in Equation 4. In another example, the source optimizing device 1100 may update the target value for the target critical dimension in Equation 7.

In at least one embodiment, as the constraint for the process parameter, a constraint on a depth of field (DOF) value may be set as a process window related to a focus area. For example, the constraint may be set such that the depth of field is above a certain value.

Referring to FIG. 9 together, a graph depicting a depth of field in a focus-dose graph is provided in FIG. 9. In the graph, a plurality of lines corresponding to the plurality of target patterns may appear, and the size of the depth of field may be proportional to the size of the area disposed at the center of the plurality of lines. For example, before the parameter update is performed, the size of the depth of field may be 120 nm.

In at least one embodiment, the source optimizing device 1100 may extract a margin killer line that limits the size of the depth of field. The source optimizing device 1100 may update a weighting value of a target pattern corresponding to the margin killer line. For example, when the margin killer line is a line corresponding to the first target pattern, the source optimizing device 1100 may increase/decrease the first target weighting value of the first target pattern by a certain magnitude. For example, the source optimizing device 1100 may update the first target weighting value such that the size of the depth of field is 140 nm or more.

The source optimizing device 1100 may generate an optimized source system by performing step S140 and step S150 again based on the updated target weighting value (refer to FIG. 4).

In another embodiment, a plurality of constraints on the plurality of process parameters may be set based on the user input UI, and the source optimizing device 1100 may additionally determine whether the plurality of constraints are all met.

A process parameter to be mainly verified may vary depending on the type of a semiconductor device to be manufactured or the type of an area of the semiconductor device. For example, when core/peri areas of a semiconductor device are manufactured, a constraint on a depth of field may be set, and when a cell area is manufactured, a constraint on a dose value related to light exposure time and a constraint on an image plane uniformity (IPU) value related to the degree of uniformity in the distribution of light may be additionally set.

In response to the determination result in step S160 that the extracted process parameter meets the constraint (all of the plurality of constraints), the source optimizing device 1100 may output the finally optimized source system in step S180. The parameters of the lithography device 1200 may then be adjusted based on the finally optimized source system (e.g., OS in FIG. 1), and a wafer WF produced using the adjusted lithography device 1200. In other words, as described in further detail below, the wafer WF may be patterned based on the optimized source system OS.

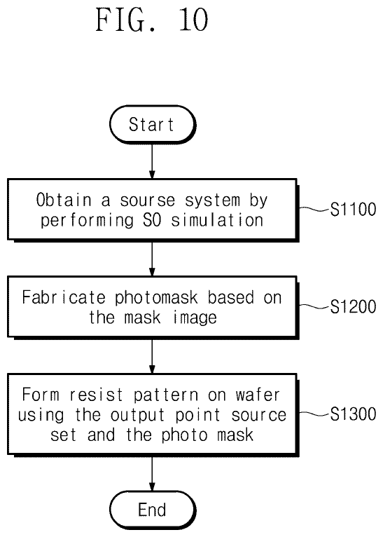

FIG. 10 is a flowchart for explaining a method of manufacturing a semiconductor device using the lithography system of FIG. 1.

Referring to FIGS. 1 and 10, the lithography system 1000 may be the same as the lithography system 1000 in FIG. 1 and may further include a mask manufacturing device that fabricates a photo mask based on a mask image.

In step S1100, the lithography system 1000 may perform the source optimization simulation according to the present disclosure, based on the mask layout ML and the user input UI. The source optimizing device 1100 may output an optimized source system as a result of the source optimization simulation.

In step S1200, the mask manufacturing device may fabricate a photo mask based on the mask layout ML. The photo mask may be a reticle on which the pattern shape of the mask layout ML is formed.

For example, the mask manufacturing device may include deposition equipment and patterning equipment for forming a pellicle on an appropriate reticle. The mask manufacturing device may form the photo mask by attaching a pellicle together with a pellicle frame to a reticle.

In step S1300, the lithography device 1200 may form a target resist pattern on the wafer WF using the photo mask. The lithography device 1200 may set a source system based on the optimized source system.

In a comparative example, a commercial tool that performs a source optimization simulation by optimizing a loss function based on an edge placement error (EPE) may be provided. In this case, to perform the source optimization simulation, for example, the loss function may be expressed as Equation 16 below.

$$s = {\sum }_{pw , eval} {W}_{P} {W}_{eval} {\vert {EPE}_{p w , eval} \vert}^{2} + {p}_{NILS} \qquad [ Equation 16 ]$$

In the case of the loss function in the comparative example, a part related to NILS is only included in a penalty function, and loss function optimization is performed in a way that minimizes the edge placement error. In the comparative example, the term for the edge placement error is provided as the square of an absolute value, and therefore a plurality of local minimum values may be calculated in a process of optimizing an objective function. That is, in the comparative example, a calculated local minimum value varies depending on an initial source system, and therefore the performance of an optimized source system may depend on the level of proficiency of a user who sets up the initial source system.

In the present disclosure, as in Equation 4, the source system optimization may be performed in a way that maximizes the objective function based on the NILS value. That is, in the present disclosure, the objective function may be expressed as a linear equation for the NILS value. Accordingly, a source system in which the objective function has a single maximum value may be output. Additionally, in the present disclosure, the target weighting value of the target pattern may be updated to meet the constraint on the process parameter. The present disclosure may output an optimized source system with improved patterning quality irrespective of the user's proficiency level.

The present disclosure provides the source optimization simulation method that outputs the source system with improved patterning quality.

The present disclosure provides the source optimization simulation method that outputs the same optimized source system irrespective of the user's proficiency level.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A non-transitory computer readable medium comprising a program code, wherein the program code, when executed by a processor, is configured to cause an apparatus including the processor to:
select a plurality of target patterns from a mask layout;
generate an aerial image based on a source system and the mask layout, the source system including a plurality of point sources;
construct an objective function based on a plurality of normalized image log-slope (NILS) values corresponding to the plurality of target patterns in the aerial image;
adjust the source system such that the objective function has an increased value; and
outputting the adjusted source system as an optimized source system,
wherein the optimized source system includes a combination of a plurality of effective factors corresponding to the plurality of point sources.

2. The non-transitory computer readable medium of claim 1, wherein each of the plurality of NILS values is calculated based on Equation 1 and Equation 2:
$$NILS = \frac{1}{I} \cdot \frac{dI}{dx} \qquad ( Equation 1 )$$
wherein, in Equation 1, x represents a coordinate on an x-axis of the aerial image, and I represents a value in the aerial image and is expressed as Equation 2 below:
$$I = {\sum }_{i} {g}_{i} {I}_{i} \qquad ( Equation 2 )$$
wherein, in Equation 2, Iᵢ represents intensity of an i-th point source among the plurality of point sources, and gᵢ represents an effective factor corresponding to the i-th point source among the plurality of effective factors,
wherein the objective function is expressed as Equation 3 in which a plurality of target weighting values are allocated to the plurality of NILS values:
$$f = {\sum }_{P} {W}_{P} {NILS}_{P} \qquad ( Equation 3 )$$
wherein, in Equation 3, NILSₚ represents a NILS value of a p-th target pattern among the plurality of target patterns, and Wp represents a target weighting value corresponding to the p-th target pattern, and
wherein the optimizing of the source system includes calculating a combination of the plurality of effective factors by which the objective function has a maximum value among the plurality of target weighting values.

3. The non-transitory computer readable medium of claim 2, wherein the program code, when executed by the processor, causes the apparatus to further set a target value for a first process parameter as an equality condition based on a user input, and
wherein the adjusting of the source system includes calculating a combination of the plurality of effective factors using a Lagrange multiplier method with the plurality of effective factors as variables, based on the objective function and the equality condition.

4. The non-transitory computer readable medium of claim 3, wherein the target value for the first process parameter is a target critical dimension (CD).

5. The non-transitory computer readable medium of claim 4, wherein the program code, when executed by the processor, causes the apparatus to further set a target value for a second process parameter as an inequality condition based on a user input, and
wherein the adjusting of the source system includes calculating a combination of the plurality of effective factors using a Lagrange multiplier method according to a Karush-Kuhn-Tucker (KKT) condition, based on the objective function, the equality condition, and the inequality condition.

6. The non-transitory computer readable medium of claim 5, wherein the target value for the second process parameter is a pupil fill ratio (PFR).

7. The non-transitory computer readable medium of claim 1, wherein the program code, when executed by the processor, causes the apparatus to further:
determine whether a constraint on a process parameter is met, based on the optimized source system;
output the optimized source system in response to a determination that the constraint on the process parameter is met; and
update a parameter of the objective function in response to a determination result that the constraint on the process parameter is not met.

8. The non-transitory computer readable medium of claim 7, wherein the determining of whether the constraint on the process parameter is met, based on the optimized source system includes:
generating an updated aerial image based on the optimized source system;
extracting a second process parameter based on the updated aerial image; and
determining whether the second process parameter meets the constraint.

9. The non-transitory computer readable medium of claim 8, wherein the constraint on the process parameter is a constraint on a depth of field, and
wherein the updating of the parameter of the objective function includes updating a weighting value of a target pattern corresponding to a margin killer line configured to limit a size of the depth of field in the objective function.

10. A computer comprising:
at least one a non-transitory storage medium configured to store a computer program; and
at least one processor configured to execute the computer program and cause the computer to:
perform a rendering on a source system including a plurality of point sources,
select a plurality of target patterns from a mask layout,
generate an aerial image based on the rendered source system and the mask layout,
construct an objective function based on a plurality of normalized image log-slope (NILS) values corresponding to the plurality of target patterns in the aerial image,
adjusting the source system such that the objective function has an increased value, and
outputting the adjusted source system as an optimized source system,
wherein the optimized source system includes a combination of a plurality of effective factors corresponding to the plurality of point sources.

11. The computer of claim 10, wherein the performing of the rendering includes performing a convolution operation using a kernel on a plurality of pixels corresponding to the plurality of point sources.

12. The computer of claim 11, wherein the rendered source system includes a plurality of rendered point sources, and
wherein an intensity distribution of each of the plurality of rendered point sources has a Gaussian distribution.

13. The computer of claim 10, wherein the objective function is a linear function for the plurality of NILS values.

14. The computer of claim 13, wherein the computer program, when executed by the computer, causes the computer to set a target value for a first process parameter as an equality condition based on a user input, and
wherein the adjusting the source system includes calculating a combination of the plurality of effective factors using a Lagrange multiplier method with the plurality of effective factors as variables, based on the objective function and the equality condition.

15. The computer of claim 14, wherein the target value for the first process parameter is a target critical dimension (CD).

16. The computer of claim 15, wherein the computer program, when executed by the computer, causes the computer to set a target value for a second process parameter as an inequality condition based on a user input, and
wherein the adjusting the source system includes calculating a combination of the plurality of effective factors using a Lagrange multiplier method according to a Karush-Kuhn-Tucker (KKT) condition, based on the objective function, the equality condition, and the inequality condition.

17. A method for manufacturing a semiconductor device using a source optimizing device, a mask manufacturing device, and a lithography device, the method comprising:
performing, by the source optimizing device, operations of
selecting a plurality of target patterns from a mask layout,
generating an aerial image based on a source system including a plurality of point sources and the mask layout,
constructing an objective function based on a plurality of normalized image log-slope (NILS) values corresponding to the plurality of target patterns in the aerial image,
adjusting the source system such that the objective function has an increased value, and
outputting the adjusted source system as an optimized source system;
fabricating, by using the mask manufacturing device, a photo mask based on the mask layout; and
forming, by using the lithography device, a resist pattern on a wafer by performing a lithography process based on an optimized source system and the photo mask.

18. The method of claim 17, wherein an intensity distribution of light of a source system of the lithography device is set based on effective factors of the plurality of point sources of the optimized source system.

19. The method of claim 18, wherein the photo mask is a transmissive photo mask, and
wherein the lithography device includes:
a light source configured to emit deep ultraviolet (DUV) light in a wavelength band of 100 nanometers to 300 nanometers;
a projection lens configured to control a shape of the light based on the optimized source system; and
at least one lens configured to apply light transmitting through the projection lens and the photo mask to the wafer.

20. The method of claim 18, wherein the photo mask is a reflective photo mask,
wherein the lithography device includes
a light source configured to generate an extreme ultraviolet (EUV) light in a wavelength band of 10 nanometers to 20 nanometers;
a source device configured to cause the light to travel toward the photo mask; and
a projection device configured to apply light reflected from the photo mask to the wafer, and
wherein the source device further includes a pupil facet mirror configured to control a shape of the light based on the optimized source system.
